(19) United States
(12) Patent Application Publication
(10) Pub. No.: US 2012/0231631 A1
(43) Pub. Date: Sep. 13, 2012

(54) PLASMA GENERATING APPARATUS AND PLASMA ETCHING METHOD USING THE SAME

(76) Inventor: Hongseub KIM, Suwon-si (KR)

(21) Appl. No.: 13/400,375

(22) Filed: Feb. 20, 2012

(30) Foreign Application Priority Data
Mar. 10, 2011 (KR) 10-2011-0021162

(51) Int. Cl. H01L 21/3065; H05H 1/24

(52) U.S. Cl. 438/710; 156/345.48; 257/E21.218

(57) ABSTRACT

A plasma generating apparatus and a plasma etching method are provided. The apparatus includes a chamber, a barrier, a susceptor, and a Radio Frequency (RF) power. The chamber forms a reaction space isolated from the external. The barrier divides the chamber into an upper chamber and a lower chamber. The barrier has a plurality of through-holes through formed to communicate the upper chamber and the lower chamber. The susceptor is installed in the lower chamber. The RF power supplies a bias power to the susceptor.

### CROSS REFERENCES

Applicant claims foreign priority under Paris Convention to Korean Patent Application No. 10-2011-0021162 filed Mar. 10, 2011, with the Korean Intellectual Property Office, where the entire contents are incorporated herein by reference.

### BACKGROUND OF THE INVENTION

1. Field of the Invention

The present invention relates to a plasma generating apparatus and a plasma etching method using the same. More particularly, the present invention relates to a plasma generating apparatus for solar cell manufacturing and a plasma etching method using the same for, by installing a barrier within a chamber and dividing a chamber internal space into an upper chamber and a lower chamber, inducing a uniform texturing reaction through separation of a reaction gas introduction space and a texturing reaction space and greatly improving texturing uniformity in a large-scale substrate.

2. Description of the Related Art

Generally, a solar cell, one of semiconductor devices for converting solar energy directly into electric energy, is a photoelectric cell fabricated by processing a silicon wafer to form a P-N junction of a Negative (N) type semiconductor and a Positive (P) type semiconductor of different polarities having majority electrons and holes, respectively, and forming an electrode, and producing electric energy through the flow of electrons by solar energy using the principles of solar power generation by the P-N junction.

Solar cells are chiefly classified into a silicon-class solar cell, such as single crystalline and polycrystalline silicon solar cells or an amorphous silicon solar cell, a compound semiconductor solar cell and the like.

The silicon-class solar cell is manufactured by cutting an ingot that is a lump of silicon at a small thickness of about 200 μm, fabricating a wafer (hereinafter, referred to as a ‘substrate’), and processing this substrate through several processes.

FIG. 1 illustrates a structure of a general solar cell. As illustrated, the solar cell is of a structure in which a texturing layer 110 is formed on a top surface of a substrate (W), an Anti Reflection Coating (ARC) 120 is lamination formed on the texturing layer 110, and front and rear electrodes 130 and 140 are formed on top and bottom surfaces of the substrate (W), respectively.

This solar cell fabrication method generally includes a texturing process (i.e., a surface texturization process) for increasing a light absorption rate of a substrate, a doping process for forming a P-N junction, an oxide film removal process for removing impurities, an ARC film forming process for reducing a loss of light reflection, a P-N junction separation process, a front/rear electrode printing process and the like.

The texturing process is a process of forming a fine texture of a pyramid shape on a top surface of the substrate (W), thereby minimizing a reflection rate of light projected to a surface of the substrate (W) and improving the efficiency of power generation of a solar cell.

The conventional texturing process carries out texturing in a wet process through a wet chemical reaction, by submerging the substrate (W) in a reaction solution using a wet equipment.

But, in a case of the wet process, a pitch and depth of a texture are large and a loss of expensive silicon is great and in addition, there is a limit in making a thickness of a silicon substrate (W) small. So, recently, active research is being made for a Reactive Ion Etching (RIE) texturing process of more finely forming a texture than the wet process and reducing a light reflection rate, thereby increasing the efficiency of a solar cell.

The RIE texturing process is a dry process of finely etching and processing a surface of a substrate (W) using plasma of a reaction gas.

But, the conventional RIE texturing process has a problem in which texturing non-uniformity in a center and edge of a substrate (W) takes place by the macro loading effect resulting from local exhaustion of an etch source due to a characteristic of an etching process using reaction gas diffusion and plasma.

Due to this, as illustrated in FIG. 2, a difference of a light reflection rate between the center of the substrate (W) and the edge occurs and the center of the substrate (W) of a low light reflection rate appears blacker than the edge. So, it fails to realize the uniformity of the whole light reflection rate.

Particularly, it is a trend in which the substrate (W) is large scaled for the sake of fabrication cost saving of a solar cell and in addition, as a system develops to collectively process a plurality of substrates (W) up to 16 to 200 wafers, texturing non-uniformity in the center and edge of the substrate (W) is getting worse.

### SUMMARY OF THE INVENTION

An aspect of exemplary embodiments of the present invention is to address at least the problems and/or disadvantages and to provide at least the advantages described below. Accordingly, an aspect of exemplary embodiments of the present invention is to isolate a reaction gas introduction space and a texturing reaction space within a chamber, thereby inducing uniform diffusion of plasma and minimizing texturing non-uniformity on a substrate.

Another aspect of exemplary embodiments of the present invention is to add a source Radio Frequency (RF) power even to an upper part of a chamber and independently control an intensity of plasma of an upper chamber and an intensity of plasma ions of a lower chamber, thereby precisely controlling a shape and size of a texture and the like.

A further aspect of exemplary embodiments of the present invention is to install pumping ports with throttle valves in an upper chamber and a lower chamber respectively to effectively control and discharge out reaction products, thereby prevent texturing non-uniformity.

According to one aspect of the present invention, a plasma generating apparatus is provided. The apparatus includes a chamber, a barrier, a susceptor, and a Radio Frequency (RF) power. The chamber forms a reaction space isolated from the external. The barrier divides the chamber into an upper chamber and a lower chamber. The barrier has a plurality of through-holes through formed to communicate the upper chamber and the lower chamber. The susceptor is installed in the lower chamber. The RF power supplies a bias power to the susceptor.

An upper pumping port with a throttle valve may be installed in the upper chamber.

A lower pumping port with a throttle value may be installed in the lower chamber.

A substrate tray mounting a plurality of substrates may be loaded on the susceptor.

A baffle plate with a plurality of discharge holes may be installed in an outer circumference of the susceptor.

The barrier may be formed of metal material.

The barrier may be formed of any one material of aluminum (Al), stainless steel (SUS), titanium (Ti), and nickel (Ni).

The barrier may be installed in a non-ground floating state.

A constant electric potential may be applied to the barrier.

The barrier may be of dielectric material.

Down-extended partitions may be provided on a lower surface of the barrier such that plasma can be uniformly distributed on upper parts of a plurality of substrates.

The partitions may be arranged in a lattice shape such that a plurality of division spaces are formed matching with the plurality of substrates.

A source RF power may be further installed and forms plasma within the upper chamber.

The source RF power may be a Capacitively Coupled Plasma (CCP) source.

The source RF power may be an Inductively Coupled Plasma (ICP) source.

A source RF power and ICP antennas may be installed over the chamber so that plasma is formed within the upper chamber.

The ICP antennas may be arranged at a constant interval on an upper part of a dielectric plate coupled to a top of the chamber.

According to another aspect of the present invention, a plasma etching method is provided. The method includes an upper chamber introduction step in which a reaction gas is introduced into an upper chamber, a lower chamber introduction step in which the reaction gas flows into a lower chamber via through-holes of a barrier, a plasma generation step of converting the reaction gas of the lower chamber into a plasma state, and a reaction-products discharge step of, at texturing reaction of the substrate by plasma, forcibly discharging reaction products generated within the lower chamber, out of the chamber.

The reaction-products discharge step may forcibly discharge out the reaction gas by means of a lower pumping port via discharge holes of a baffle plate installed in a susceptor.

After the reaction products of the lower chamber flow upward into the upper chamber, the reaction-products discharge step may forcibly discharge out the reaction products by means of an upper pumping port installed in the upper chamber.

The reaction-products discharge step may independently, forcibly discharge the reaction products of the lower chamber and the reaction products flowing into the upper chamber, by means of all of an upper pumping port and a lower pumping port.

### BRIEF DESCRIPTION OF THE DRAWINGS

The above and other objects, features and advantages of the present invention will become more apparent from the following detailed description when taken in conjunction with the accompanying drawings in which:

FIG. 1 is a cross section illustrating a schematic structure of a general solar cell;

FIG. 2 is a photograph illustrating a light reflection rate of a substrate that is processed in a conventional Reactive Ion Etching (RIE) texturing method;

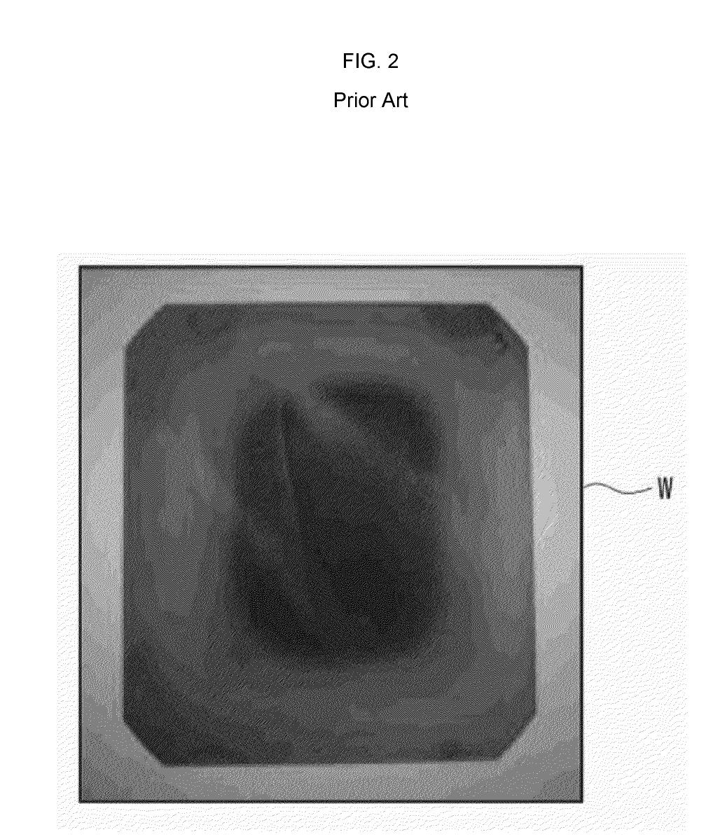

FIG. 3 is a diagram illustrating a construction of a plasma generating apparatus according to an exemplary embodiment of the present invention;

FIG. 4 is a plane diagram illustrating a barrier according to the present invention;

FIG. 5 is a plane diagram illustrating a substrate tray and a barrier projected to the substrate tray according to the present invention;

FIG. 6 is a diagram illustrating a construction of a plasma generating apparatus according to another exemplary embodiment of the present invention;

FIG. 7 is a photograph illustrating a light reflection rate of a substrate that is textured in a plasma generating apparatus according to the present invention; and

FIG. 8 is a flowchart illustrating a plasma etching method according to the present invention.

Throughout the drawings, the same drawing reference numerals will be understood to refer to the same elements, features and structures.

### DETAILED DESCRIPTION OF THE INVENTION

Exemplary embodiments of the present invention will now be described in detail with reference to the annexed drawings. In the following description, a detailed description of known functions and configurations incorporated herein has been omitted for conciseness.

The present invention is characterized by securing texturing uniformity on a substrate (W) by applying a plasma generating apparatus dividing a reaction space within a chamber 1 into an upper part and a lower part. The present invention is to realize a uniform and low light reflection rate throughout the surface of the substrate (W), by forming a fine texture on the substrate (W) using a Reactive Ion Etching (RIE) texturing process.

Texturing is to form a pyramid-shape or porous texture in a surface of the substrate (W), minimizing the reflection of incident light.

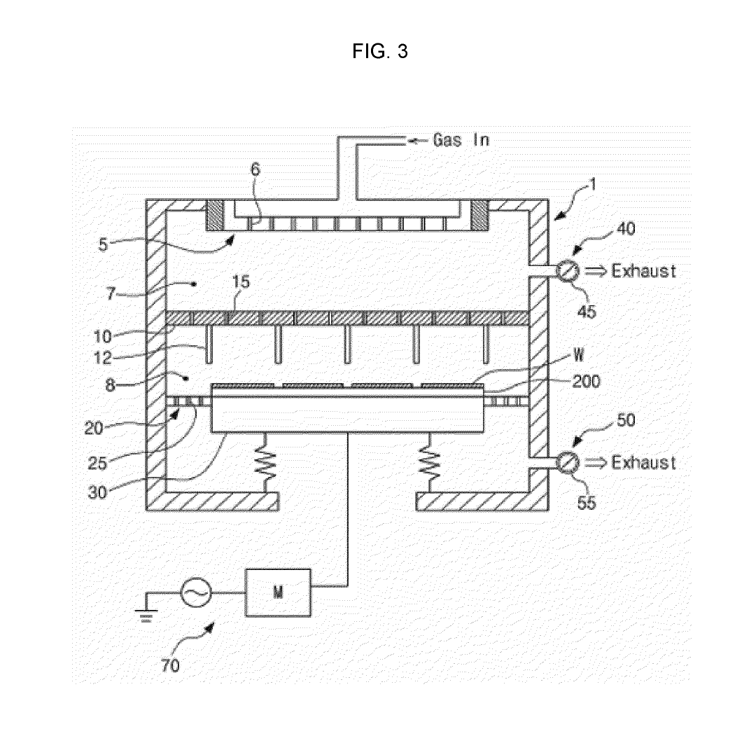

A plasma generating apparatus according to the present invention is described below in detail with reference to FIGS. 3 to 5.

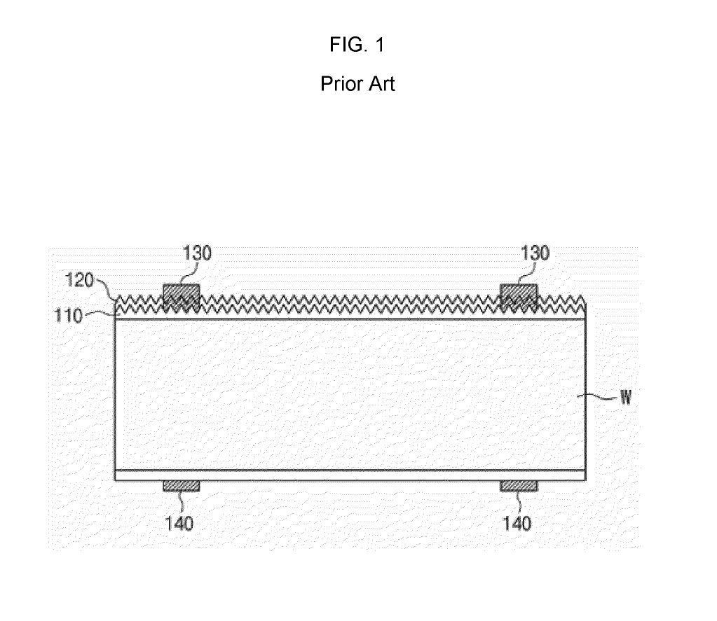

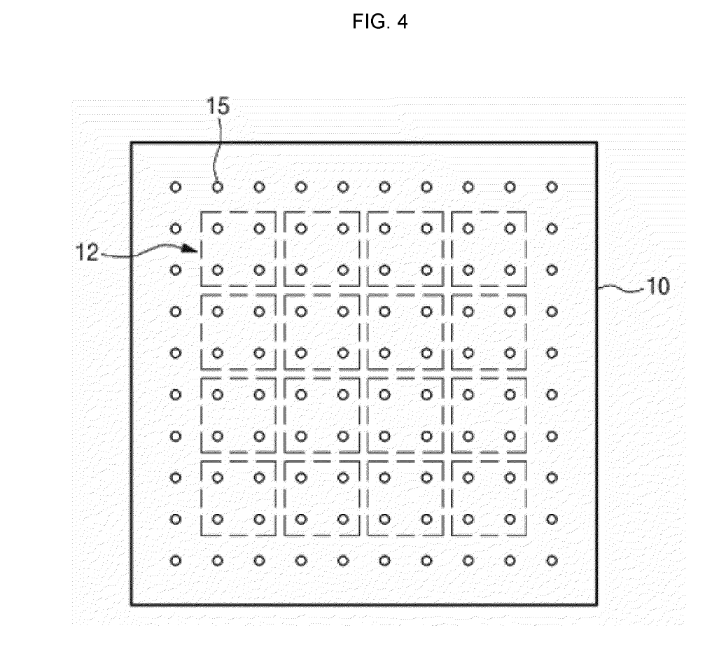

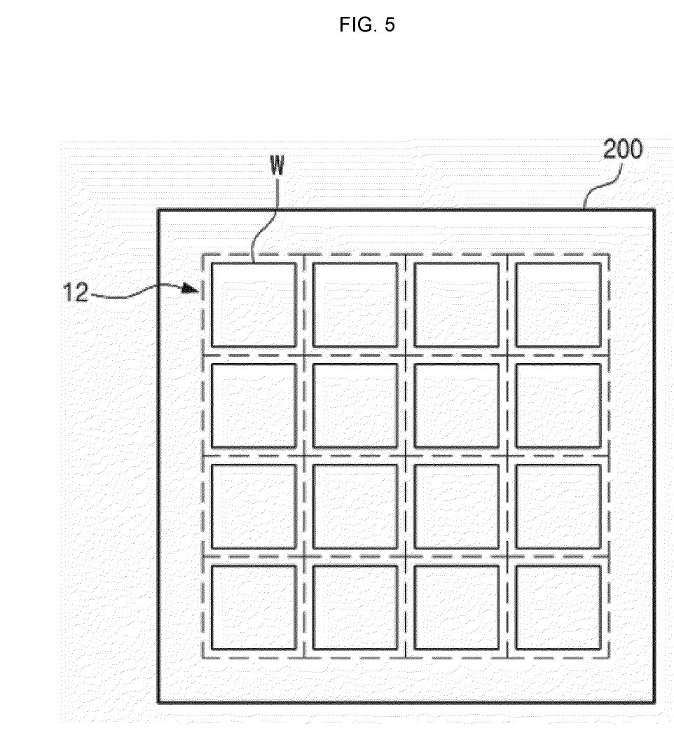

FIG. 3 illustrates a construction of a plasma generating apparatus according to an exemplary embodiment of the present invention. FIG. 4 is a plane diagram illustrating a barrier of FIG. 1. FIG. 5 is a plane diagram illustrating a substrate tray and a barrier projected to the substrate tray according to the present invention.

As illustrated in FIG. 3, the plasma generating apparatus of the present invention includes a chamber 1, a barrier 10, a susceptor 30, and a Radio Frequency (RF) power 70.

The chamber 1 provides a plasma reaction space isolated from the external. The chamber 1 has a sealed internal space of a constant size, and may be grounded and provided to have various sizes and forms according to a size of a substrate (W) or a process characteristic.

A gas injector 5 is installed in an upper part of the chamber 1.

The gas injector 5 performs a role of injecting a reaction gas into the chamber 1. The gas injector 5 is connected with a separate gas supply unit (not shown). The gas injector 5 can be constructed to have a plurality of injection holes 6. The injection holes 6 are arranged such that a reaction gas can rapidly and uniformly diffuse for distribution within the chamber 1.

The gas injector 5 may be provided in a shower head form such as a Gas Distribution Plate (GDP) form or common various forms such that a reaction gas can be injected using the plurality of injection holes 6 at the same time.

The reaction gas can be various kinds of gases according to a texturing process, but can be commonly a CxFx or SxFx class gas.

The barrier 10 is installed within the chamber 1.

The barrier 10 is to separate a reaction space within the chamber 1 into an upper chamber 7 and a lower chamber 8. The barrier 10 can be provided to have a plate form of a constant thickness. The barrier 10 is installed in horizontal direction within the chamber 1.

At this time, the barrier 10 is installed in parallel with the substrate (W) to be spaced a constant distance apart and face the substrate (W). The barrier 10 has an outer circumference surface, which matches with an inner circumference surface of the chamber 1 and is fixed to an inner wall of the chamber 1.

Also, the barrier 10 can be formed of various metal materials. Desirably, the barrier 10 is formed of any one material of aluminum (Al), stainless steel (SUS), titanium (Ti), and nickel (Ni).

In a case where the barrier 10 is formed of metal material as above, the barrier 10 may be insulated from the chamber 1 and installed in a floating state (i.e., a non-grounded state), or may be manufactured of dielectric material.

Also, the barrier 10 can connect with a separate power (not shown) to have a plus (+) or minus (−) electric potential.

In a case where the barrier 10 has a constant electric potential as above, the barrier 10 can improve the uniformity of plasma.

Meanwhile, the barrier 10 has a plurality of through-holes 15 that are through formed in up/down directions.

The through-holes 15 are arranged to be spaced a constant interval apart. As illustrated in FIGS. 3 and 4, the through-holes 15 are arranged such that they are correspondingly positioned over substrates (W) loaded on a substrate tray 200.

As illustrated in FIG. 4, the through-holes 15 are arranged to match with the respective substrates (W) in a set of four through-holes, but are not limited to this. The through-holes 15 may be arranged in various forms and numbers according to a size or form of the substrate (W) or a process characteristic.

Generally, a reaction gas cannot form uniform plasma because of a difference of the extent of diffusion in a process of reaching a center of a substrate (W) and an edge (i.e., an outer circumference). Due to this, the substrate (W) generates a difference of texturing between its center and edge.

To remove this, the barrier 10 restricts a plasma reaction space.

Meanwhile, a plurality of partitions 12 can be installed on a bottom surface of the barrier 10.

The partitions 12 are to induce a rapid and uniform diffusion of a reaction gas, which is introduced from top to bottom through the through-holes 15, on respective substrates (W) and generate plasma, thereby improving the texturing uniformity of the substrates (W).

The partition 12 is down installed at a constant length. As illustrated in FIGS. 3 and 4, the partitions 12 are provided to form a lattice shape matching with a position of the substrate (W) so that a plasma reaction space is divided and formed on an upper part of each substrate (W).

But, the partitions 12 are not limited to the above structure, and may be formed so that a plurality of substrates (W) are included within one lattice.

Meanwhile, the substrate (W) is loaded within the chamber 1 with the substrate (W) safely mounted on the substrate tray 200. For productivity improvement, the substrate (W) may be provided plurally.

The substrate tray 200 is supported by the susceptor 30.

The susceptor 30 is installed in the center of the lower chamber 8, and is connected to the RF power 70 for applying a bias power for generating plasma of a reaction gas.

The RF power 70 has a matching box for impedance control, and applies a high frequency bias power to the susceptor 30 and generates plasma in the lower chamber 8.

Meanwhile, a baffle plate 20 can be installed in the susceptor 30 for uniform plasma diffusion in the lower chamber 8.

The baffle plate 20 is out inserted to the susceptor 30 and is installed. The baffle plate 20 has a plurality of discharge holes 25 for controlling the distribution of reaction products. The baffle plate 20 has an inner circumference surface coupled to an outer circumference surface of the susceptor 30, and has an outer circumference surface coupled and fixed to an inner circumference surface of the chamber 1.

An upper pumping port 40 and a lower pumping port 50 have throttle valves 45 and 55, respectively, and can be installed in the upper chamber 7 and the lower chamber 8, respectively.

The upper pumping port 40 and the lower pumping port 50 are for controlling a discharge of a reaction gas within the chamber 1, reaction products such as polymer or particles and the like. Any one or both of the upper and lower pumping ports 40 and 50 can be installed in the chamber 1.

The upper and lower pumping ports 40 and 50 can have exhaust pumps, respectively, and suitably forcibly discharge out the reaction products and the like according to a process progress.

An operation process of a plasma generating apparatus according to the present invention is described below.

First, a reaction gas is injected into the upper chamber 7 through the injection holes 6 of the gas injector 5 installed in the upper part of the chamber 1.

The injected reaction gas uniformly enters and diffuses into the lower chamber 8 through the through-holes 15 of the barrier 10.

At this time, a bias power from the RF power 70 is applied to the susceptor 30. Due to this, the reaction gas having diffused into the lower chamber 8 converts into a plasma state and reacts with the substrate (W).

In detail, the reaction gas diffuses into the lower chamber 8 of the chamber 1 and simultaneously, converts into the plasma state by an RF power applied to the susceptor 30. This plasma gets in contact and physically or chemically reacts with a surface of the substrate (W), thereby forming a fine texture in the surface of the substrate (W).

The plasma formed in the lower chamber 8 uniformly diffuses and stays in the lower chamber 8 of a restricted size during a constant time by virtue of the barrier 10. At this time, the surface of the substrate (W) is etched by a physical reaction using ion energy of plasma and forms the fine texture, thereby achieving texturing treatment.

Also, the plasma is uniformly formed matching with respective substrates (W) on upper parts of the substrates (W) by the partitions 12 installed in the barrier 10, thereby preventing texturing non-uniformity from occurring at a center and edge of the substrate (W) by the macro loading effect.

A plasma reaction process is that reactive ions or radicals are incident on a surface of a silicon (Si) substrate (W) and react with the substrate (W).

At this time, reaction products, i.e., a high-vapor-pressure compound (SiF₄, etc.) and a low-vapor-pressure compound (SiₓO_{y}F_{z}, etc.) are formed.

The high-vapor-pressure reaction products are easily pumped and discharged out, but the low-vapor-pressure reaction products are not easily pumped and are accumulated on the surface of the substrate (W).

That is, owing to the barrier 10, the low-vapor-pressure reaction products are not easily discharged out of the lower chamber 8 and are again absorbed to the substrate (W). The absorbed reaction products form a micro mask.

By virtue of the thus formed micro mask, plasma reaction is selectively performed and a texture of a micro size is formed, whereby the substrate (W) surface is textured.

At this time, to obtain uniform texturing, a density and uniform distribution of the low-vapor-pressure reaction products within the chamber 1 are very significant.

Accordingly, in the present invention, among the reaction products generated in the lower chamber 8, the high-vapor-pressure reaction products rapidly diffuse to the whole upper and lower chambers 7 and 8. Unlike this, because a vapor pressure is low, the low-vapor-pressure reaction products stay in the lower chamber 8 in virtue of the barrier 10 while the low-vapor-pressure reaction products achieve uniform diffusion and distribution and are continuously absorbed to the surface of the substrate (W), forming a texture by a texturing reaction.

In a case where only the upper pumping port 40 is provided, plasma, reaction products and the like of the lower chamber 8 are again forcibly introduced into the upper chamber 7 and are discharged out of the upper chamber 7 by virtue of the upper pumping port 40. Also, in a case where only the lower pumping port 50 is provided, the plasma, the reaction products and the like are discharged out of the lower chamber 8 via the discharge holes 25 of the baffle plate 20. In a case where the upper and lower pumping ports 40 and 50 are all provided, the upper and lower pumping ports 40 and 50 each control and discharge out the plasma, the reaction products and the like independently.

Accordingly, the upper and lower pumping ports 40 and 50 suitably control the distribution of plasma or reaction products of the upper and lower chambers 7 and 8 independently.

If the texturing process is completed, the substrate tray 200 is drawn out, a subsequent substrate tray 200 is loaded, and the same process is performed.

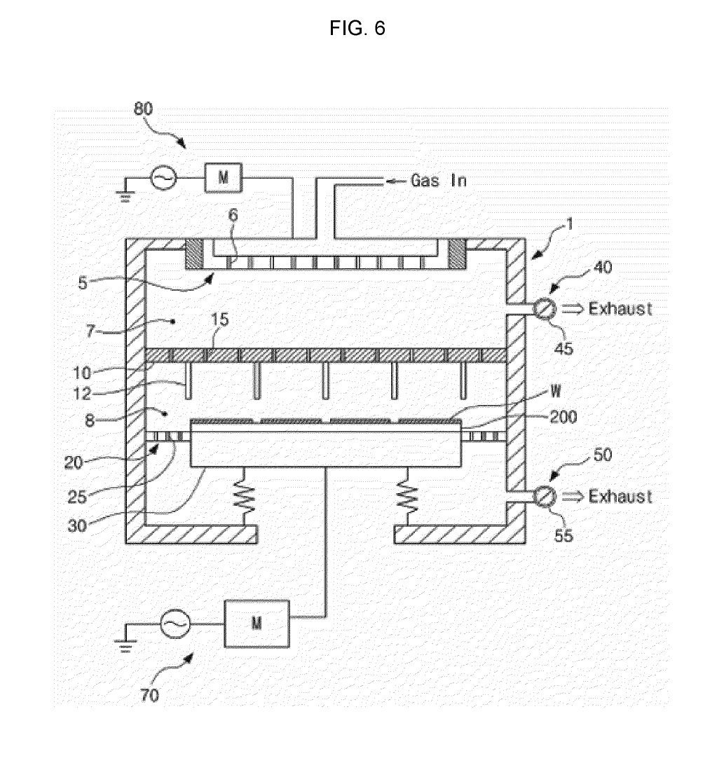

Plasma generating apparatuses according to other exemplary embodiments of the present invention are described below with reference to FIG. 6.

FIG. 6 illustrate constructions of plasma generating apparatuses according to other exemplary embodiments of the present invention. FIG. 6 illustrate the same constructions as FIG. 3 excepting a source RF power 80 installed over a chamber 1 in FIG. 6. Thus, only a modified construction is described.

As illustrated in FIG. 6, the source RF power 80 can be a Capacitively Coupled Plasma (CCP) source or an ICP source. The source RF power 80 is installed connecting to a gas injector 5 and converts a reaction gas, which is introduced into an upper chamber 7, into a plasma state.

Accordingly, in the exemplary embodiment of FIG. 6, plasma is simultaneously generated in the upper chamber 7 and a lower chamber 8. At this time, the source RF power 80 controls an intensity of plasma of the upper chamber 7, and an RF power 70 of a lower part independently controls an intensity of plasma ions of the lower chamber 8, thereby being capable of precisely controlling plasma and precisely controlling a size or depth of a texture formed in a top surface of a substrate (W).

After reaction is completed, remnant reaction gas or reaction products are discharged out through an upper pumping port 40 and a lower pumping port 50, respectively.

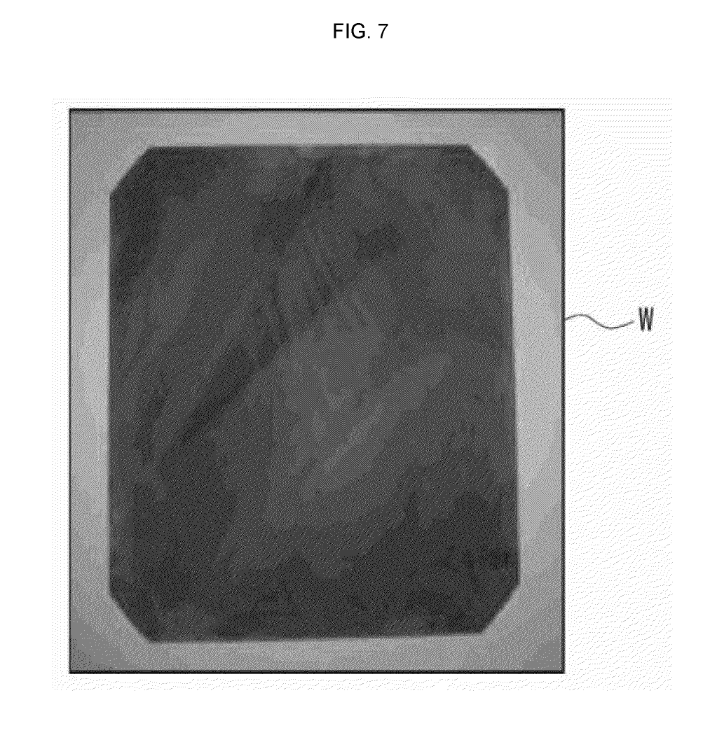

FIG. 7 is a photograph illustrating a light reflection rate of a texturing completed substrate (W) in a plasma generating apparatus according to the present invention.

As illustrated, it can be appreciated that, since texturing uniformity in the whole surface of the substrate (W) is secured, a difference of a light reflection rate between a center of the substrate (W) and an edge does not appear.

Due to this, the efficiency of power generation of a solar cell can be improved.

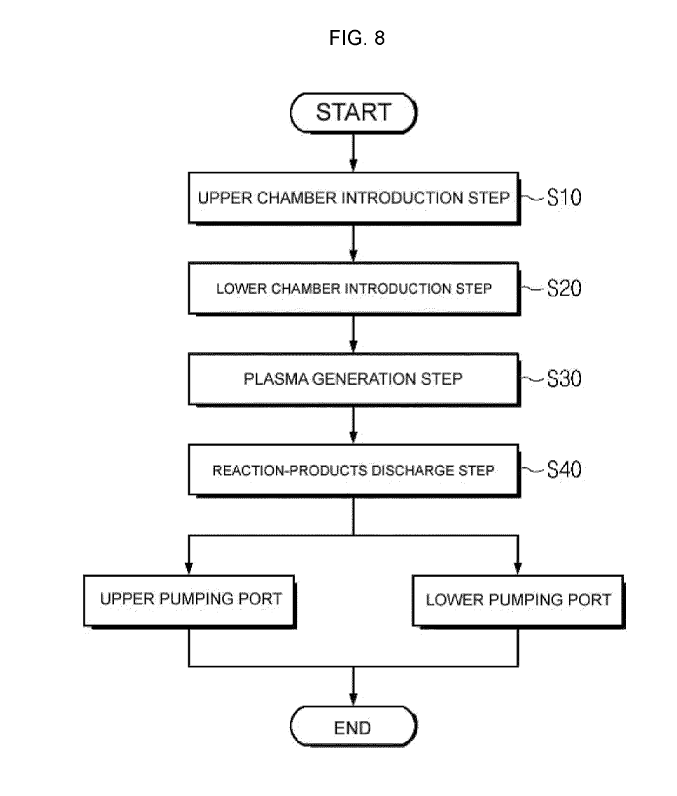

A plasma etching method of the present invention is described below with reference to FIG. 8.

FIG. 8 is a flowchart illustrating a plasma etching method according to the present invention.

As illustrated, the plasma etching method includes an upper chamber introduction step (S10), a lower chamber introduction step (S20), a plasma generation step (S30), and a reaction-products discharge step (S40).

The upper chamber introduction step (S10) is a step in which a reaction gas is injected and diffuses into an upper chamber 7 through a gas injector 5 installed over a chamber 1.

The lower chamber introduction step (S20) is a step in which the reaction gas introduced into the upper chamber 7 flows into a lower chamber 8 via through-holes 15 of a barrier 10.

The plasma generation step (S30) is a step of, in a state where the reaction gas flows into the lower chamber 8 as above, applying an RF power to a susceptor 30 and converting the reaction gas within the lower chamber 8 into a plasma state.

If the reaction gas within the lower chamber 8 converts into the plasma state as above, plasma reacts with and etching processes a surface of a substrate (W). At this time, reaction products are generated.

That is, the plasma reaction process generates high-vapor-pressure reaction products, low-vapor-pressure reaction products and the like.

At this time, the high-vapor-pressure reaction products easily flow upward into the upper chamber 7 through the through-holes 15 of the barrier 10 because a vapor pressure is high, and the low-vapor-pressure reaction products stay as being absorbed to the substrate (W) surface.

The above remnant reaction products perform a role of micro masking and, in a plasma etching process, form a fine texture in the substrate (W) surface.

While the reaction is in progress, the reaction-products discharge step (S40) forcibly discharges the remnant gases, reaction products and the like out of the upper chamber 7 and the lower chamber 8 using an upper pumping port 40 and a lower pumping port 50.

The reaction-products discharge step (S40) can open only the upper pumping port 40 and forcibly discharge the reaction products and the like out of the upper chamber 7, or can open only the lower pumping port 50 and forcibly discharge the reaction products and the like out of the lower chamber 8 via discharge holes 25 of a baffle plate 20.

Also, the reaction-products discharge step (S40) may open all of the upper pumping port 40 and the lower pumping port 50 and rapidly, independently discharge remnant gas, reaction products and the like out of the upper chamber 7 and the lower chamber 8, respectively.

Accordingly, by dividing the chamber 1 into the upper chamber 7 and the lower chamber 8, the present invention can induce uniform diffusion of plasma, perform an effective texturing process, and minimize texturing non-uniformity on the substrate (W) and also, can independently control an intensity of plasma and an intensity of plasma ions and precisely control a form and size of a texture on the substrate (W), minimizing a light reflection rate of the substrate (W).

As described above, the present invention not only has an effect of increasing the efficiency of power generation of a solar cell through the improvement of texturing uniformity in a center and edge of a substrate but also has an effect of improving a throughput of the solar cell through precise and efficient texturing control, thereby achieving productivity improvement and fabrication cost saving.

While the invention has been shown and described with reference to a certain preferred embodiment thereof, it will be understood by those skilled in the art that various changes in form and details may be made therein without departing from the spirit and scope of the invention as defined by the appended claims.

What is claimed is:

1. A plasma generating apparatus comprising:
a chamber for forming a reaction space isolated from the external;
a barrier for dividing the chamber into an upper chamber and a lower chamber, the barrier having a plurality of through-holes through formed to communicate the upper chamber and the lower chamber;
a susceptor installed in the lower chamber; and
a Radio Frequency (RF) power for supplying a bias power to the susceptor.

2. The apparatus of claim 1, wherein an upper pumping port with a throttle valve is installed in the upper chamber.

3. The apparatus of claim 2, wherein a lower pumping port with a throttle value is installed in the lower chamber.

4. The apparatus of claim 1, wherein a substrate tray mounting a plurality of substrates is loaded on the susceptor.

5. The apparatus of claim 1, wherein a baffle plate with a plurality of discharge holes is installed in an outer circumference of the susceptor.

6. The apparatus of claim 1, wherein the barrier is formed of metal material.

7. The apparatus of claim 6, wherein the barrier is formed of any one material of aluminum (Al), stainless steel (SUS), titanium (Ti), and nickel (Ni).

8. The apparatus of claim 6, wherein the barrier is installed in a non-ground floating state.

9. The apparatus of claim 6, wherein a constant electric potential is applied to the barrier.

10. The apparatus of claim 1, wherein the barrier is of dielectric material.

11. The apparatus of claim 1, wherein down-extended partitions are provided on a lower surface of the barrier such that plasma can be uniformly distributed on upper parts of a plurality of substrates.

12. The apparatus of claim 11, wherein the partitions are arranged in a lattice shape such that a plurality of division spaces are formed matching with the plurality of substrates.

13. The apparatus of claim 1, wherein a source RF power is further installed and forms plasma within the upper chamber.

14. The apparatus of claim 13, wherein the source RF power is a Capacitively Coupled Plasma (CCP) source.

15. The apparatus of claim 13, wherein the source RF power is an Inductively Coupled Plasma (ICP) source.

16. A plasma etching method comprising:
an upper chamber introduction step in which a reaction gas is introduced into an upper chamber;
a lower chamber introduction step in which the reaction gas flows into a lower chamber via through-holes of a barrier;
a plasma generation step of converting the reaction gas of the lower chamber into a plasma state; and
a reaction-products discharge step of, at texturing reaction of the substrate by plasma, forcibly discharging reaction products generated within the lower chamber, out of the chamber.

17. The method of claim 16, wherein the reaction-products discharge step forcibly discharges out the reaction gas by means of a lower pumping port via discharge holes of a baffle plate installed in a susceptor.

18. The method of claim 16, wherein, after the reaction products of the lower chamber flow upward into the upper chamber, the reaction-products discharge step forcibly discharges out the reaction products by means of an upper pumping port installed in the upper chamber.

19. The method of claim 16, wherein the reaction-products discharge step independently, forcibly discharges the reaction products of the lower chamber and the reaction products flowing into the upper chamber, by means of all of an upper pumping port and a lower pumping port.
